(19) United States
(12) Patent Application Publication
(10) Pub. No.: US 2003/0219989 A1
(43) Pub. Date: Nov. 27, 2003

(54) Semiconductor device producing method and semiconductor device producing apparatus

(76) Inventors: Tadashi Terasaki, Tokyo (JP); Shinji Yashima, Tokyo (JP)

Correspondence Address: BIRCH STEWART KOLASCH & BIRCH, PO BOX 747, FALLS CHURCH, VA, 22040-0747, US

(21) Appl. No.: 10/405,637

(22) Filed: Apr. 3, 2003

(30) Foreign Application Priority Data
Apr. 3, 2002 (JP) 2002-101103
May 21, 2002 (JP) 2002-145759

(51) Int. Cl. H01L 21/302

(52) U.S. Cl. 438/725

(57) ABSTRACT

A producing method of a semiconductor device uses a plasma processing apparatus including a processing chamber, a substrate supporting body which is to support a substrate in the processing chamber, and a cylindrical electrode and a magnetic lines of force-forming device which are disposed around the processing chamber. The producing method comprises supplying gas including oxygen element into the processing chamber, and plasma-discharging the gas including oxygen element by a high frequency electric field obtained by supplying a high frequency electric power to the cylindrical electrode and a magnetic field obtained by the magnetic lines of force-forming device to oxidize an object to form an oxide film having a thickness of 30 to 60 Å.

### BACKGROUND OF THE INVENTION

1. Field of the Invention

The present invention relates to a semiconductor device producing method and a semiconductor device producing apparatus, more particularly, to a semiconductor device producing method and a semiconductor device producing apparatus for processing a substrate using a modified magnetron typed plasma processing apparatus, and still more particularly, to a method and an apparatus for subjecting a substrate surface to nitriding processing or oxidation processing.

2. Description of the Related Art

In procedure for producing a semiconductor device, there exists a step for subjecting a substrate surface to nitriding processing or oxidation processing. A CVD (Chemical Vapor Deposition) method is generally used in this step, and it is required that a thickness of a film which is subjected to the nitriding processing or the oxidation processing by the CVD method is increased. As a CVD apparatus which satisfies this requirement, there exist a plasma processing apparatus and a high temperature thermal processing apparatus.

As the plasma processing apparatus, there are known a parallel flat plate type plasma processing apparatus. In the apparatus, in order to increase the thickness of the nitride film or the oxide film, an output value of high frequency electric power (RF electric power) for bringing gas into plasma state is controlled, a high frequency electric power source for applying bias is connected to a susceptor on which the substrate is to be placed and bias electric power to be supplied to the susceptor is controlled. In the high temperature thermal processing apparatus, in order to increase the thickness of the nitride film or the oxide film, it is necessary to increase a processing temperature to 700° C. and thermal processing is carried out for a long time.

According to the method for controlling the output value of RF electric power using the parallel flat plate type plasma processing apparatus, however, even if the output value of the RF electric power is increased from 500W to 2,000W as shown in FIG. 6 for example, the film thickness is only increased to about 3 nm at most. Further, if the film thickness is increased, uniformity of the film thickness over the entire surface of the film is deteriorated to about ±10 to ±15%. In the case of the method for controlling the bias electric power, since it is necessary to connect the high frequency electric power source or low frequency electric power source is connected to the susceptor, the apparatus becomes complicated and expensive.

In the case of the method for increasing the processing temperature using the high temperature thermal processing apparatus, after a transistor is formed, if a device is exposed to a high temperature for a long time, characteristics of the transistor are largely deteriorated. Therefore, it is not preferable that a nitride film or oxide film having a thickness of 3 nm or more is formed by the high temperature processing.

### SUMMARY OF THE INVENTION

It is a main object of the present invention to provide a producing method of a semiconductor device and a semiconductor device producing apparatus capable of uniformly and inexpensively forming a thick film at a low temperature when a substrate surface is subjected to nitriding processing or oxidation processing.

According to a first aspect of the present invention, there is provided a producing method of a semiconductor device using a plasma processing apparatus including a processing chamber, a substrate supporting body which is to support a substrate in the processing chamber, and a cylindrical electrode and a magnetic lines of force-forming device which are disposed around the processing chamber, comprising:

supplying gas including oxygen element into the processing chamber, and

plasma-discharging the gas including oxygen element by a high frequency electric field obtained by supplying a high frequency electric power to the cylindrical electrode and a magnetic field obtained by the magnetic lines of force-forming device to oxidize an object to form an oxide film having a thickness of 30 to 60 Å.

According to a second aspect of the present invention, there is provided a producing method of a semiconductor device using a plasma processing apparatus including a processing chamber, a substrate supporting body which is to support a substrate in the processing chamber, a coil and a capacitor which are connected between the substrate supporting body and a reference potential, and a cylindrical electrode and a magnetic lines of force-forming device which are disposed around the processing chamber, comprising:

supplying substrate processing gas into the processing chamber, and

plasma-discharging the substrate processing gas by a high frequency electric field obtained by supplying a high frequency electric power to the cylindrical electrode and a magnetic field obtained by the magnetic lines of force-forming device to form an oxide film, a nitride film or an oxynitride film, wherein

a thickness of the oxide film, a thickness of the nitride film or a thickness of the oxynitride film is changed by changing at least a number of windings of the coil or changing a capacity of the capacitor.

According to a third aspect of the present invention, there is provided a semiconductor device producing apparatus, comprising:

a processing chamber;

a substrate supporting body which is to support a substrate in the processing chamber;

a coil and a capacitor which are connected between the substrate supporting body and a reference potential, at least one of a number of windings of the coil and a capacity of the capacitor being variable; and

a cylindrical electrode and a magnetic lines of force-forming device which are disposed around the processing chamber, wherein

substrate processing gas is supplied into the processing chamber, and

the substrate processing gas is plasma-discharged by a high frequency electric field obtained by supplying a high frequency electric power to the cylindrical electrode and a magnetic field obtained by the magnetic lines of force-forming device.

According to a fourth aspect of the present invention, there is provided a semiconductor device producing apparatus, comprising:

a processing chamber;

a substrate supporting body which is to support a substrate in the processing chamber; and

a cylindrical electrode and a magnetic lines of force-forming device which are disposed around the processing chamber, wherein

substrate processing gas is supplied into the processing chamber,

the substrate processing gas is plasma-discharged by a high frequency electric field obtained by supplying a high frequency electric power to the cylindrical electrode and a magnetic field obtained by the magnetic lines of force-forming device to form an oxide film, a nitride film or an oxynitride film, and

a thickness of the oxide film, a thickness of the nitride film or a thickness of the oxynitride film is changed by changing one of an electric potential of the substrate supporting body, an impedance of the substrate supporting body, and an electric potential difference between the substrate supporting body and a plasma producing region.

According to a fifth aspect of the present invention, there is provided a producing method of a semiconductor device using a plasma processing apparatus including a processing chamber, a substrate supporting body which is to support a substrate in the processing chamber, and a cylindrical electrode and a magnetic lines of force-forming device which are disposed around the processing chamber, comprising:

supplying substrate processing gas into the processing chamber, and

plasma-discharging the substrate processing gas by a high frequency electric field obtained by supplying a high frequency electric power to the cylindrical electrode and a magnetic field obtained by the magnetic lines of force-forming device to form an oxide film, a nitride film or an oxynitride film, wherein

a thickness of the oxide film, a thickness of the nitride film or a thickness of the oxynitride film is changed by changing one of an electric potential of the substrate supporting body, an impedance of the substrate supporting body, and an electric potential difference between the substrate supporting body and a plasma producing region.

### BRIEF DESCRIPTION OF THE DRAWINGS

The above and further objects, features and advantages of the present invention will become more apparent from the following detailed description taken in conjunction with the accompanying drawings, wherein:

FIG. 1A is a diagram showing a thickness of an oxide film and a film thickness uniformity over the entire surface with respect to a capacity variable amount of a variable capacitor;

FIG. 1B is a high frequency electric potential characteristics diagram of a susceptor with respect to a capacity variable amount of a variable capacitor;

FIG. 2 is a longitudinal sectional view of a single substrate processing type modified magnetron typed plasma processing apparatus (MMT) which carries out a producing method of a semiconductor device of the present invention;

FIG. 3 is a circuit diagram showing an impedance variable mechanism according to an embodiment of the present invention;

FIG. 4 is a circuit diagram showing an impedance variable mechanism according to another embodiment of the present invention;

FIG. 5 is a film thickness characteristics diagram with respect to a high frequency current according to another embodiment of the present invention;

FIG. 6 is a diagram showing a thickness of an oxide film and a film thickness uniformity over the entire surface with respect to a value of high frequency electric power according to a conventional plasma processing apparatus; and

FIG. 7 is schematic longitudinal sectional view for explaining a nonvolatile memory to which an MMT apparatus according to the present invention is preferably applied.

### DESCRIPTION OF THE PREFERRED EMBODIMENTS

According to a preferred embodiment of the present invention, there is provided a producing method of a semiconductor device for processing a substrate using a modified magnetron typed plasma processing apparatus, wherein plasma produced by allowing gas which becomes a nitriding source or an oxidizing source to magnetron-discharge is controlled by adjusting potential of the substrate, and a surface of the substrate is subjected to nitriding processing or oxidation processing by the controlled plasma.

Here, the modified magnetron typed plasma processing apparatus generates magnetron discharge by forming a high frequency electric field and a magnetic field to produce high density plasma, and this apparatus can control energy of ions incident onto a substrate independently from plasma production. Since such a modified magnetron typed plasma processing apparatus is used, if the potential of the substrate is adjusted, the energy of ions incident onto the substrate can be controlled independently, and it is possible to change the plasma producing efficiency. Therefore, as compared with a case in which high frequency electric power is controlled for producing plasma, it is possible to form a thick nitride film or oxide film on a surface of the substrate, and to uniform the film thickness over its entire surface.

Preferably, the above-mentioned processing step, its antecedent step and subsequent step are continuously carried out in the same vacuum chamber. If the above-mentioned processing step, its antecedent step and subsequent step are continuously carried out in the same vacuum chamber, it is possible to stably carry out the nitriding processing or oxidation processing, and to enhance the characteristics of the semiconductor device.

According to another preferred embodiment of the present invention, there is provided a producing apparatus of a semiconductor device comprising a vacuum container which comprises a modified magnetron typed plasma processing apparatus and which is formed therein with a plasma producing region and processes a substrate, a gas-introducing system for introducing film-forming gas into the vacuum container, a discharging electrode which is disposed on an outer periphery of said vacuum container, which forms electric field in the plasma producing region, and which allows the film-forming gas introduced into the vacuum container to discharge, high frequency electric power applying means for applying high frequency electric power for forming electric field to the discharging electrode, magnetic lines of force-forming means which is disposed on the outer periphery of the vacuum container and which forms magnetic lines of force in the plasma producing region and acquires electric charge generated by the discharging, a vacuum exhausting system which exhausts the vacuum container to control a pressure in the vacuum container, heating means for heating a susceptor in the vacuum container, and an impedance variable mechanism which is connected to the susceptor and which is capable of adjusting impedance between a substrate and the ground.

An embodiment of the present invention will be explained below with reference to the drawings. As a plasma CVD processing apparatus for carrying out a producing method of a semiconductor device of the present invention, a modified magnetron typed plasma processing apparatus (MMT apparatus, hereinafter) capable of producing high density plasma by electric field and magnetic field is used. In the MMT apparatus, a substrate is placed in an air-tight reaction chamber, substrate processing gas is introduced into the reaction chamber through a gas shower plate, a pressure in the reaction chamber is maintained at a constant value, high frequency electric power is supplied to a discharging electrode to form an electric field, and a magnetic field is applied to the discharging electrode to cause magnetron discharge. Electrons discharged from the discharging electrode keeps cycloid motion and orbits while drifting, thereby elongating its lifetime and enhancing an ionization/generating ratio and thus, high density plasma can be produced. Film-forming gas is excited and decomposed by the plasma to cause chemical reaction, thereby forming a thin film on a substrate surface. It is possible to obtain higher density plasma as compared with a conventionally commonly used capacitive coupling type plasma processing apparatus of course and a plasma CVD processing apparatus.

FIG. 2 shows an outline structure of such an MMT apparatus. The MMT apparatus has a cylindrical vacuum container 2 which forms a reaction chamber 1 therein. The vacuum container 2 comprises a lower container 3 and an upper container 4 which is placed on the lower container. The upper container 4 is made of domical aluminum oxide (alumina) or quartz, and the lower container 3 is made of aluminum. A later-described susceptor 5 which is integrally provided with a heater is made of aluminum nitride, ceramics or quartz, thereby reducing an amount of metal contaminant introduced into a film when the film is processed.

The vacuum container 2 is provided at its upper portion with a gas-introducing opening 6. The gas-introducing opening 6 is connected to a shower head 8 having gas-injecting holes 7 provided in an upper wall of the shower head 8 which is opposed to the substrate W. Film-forming gas which becomes a nitriding source or an oxidizing source is supplied from the gas-injecting holes 7 into the vacuum container 2. The vacuum container 2 is provided at its bottom with a gas-exhausting opening 12 so that gas after processing flows toward the bottom of the vacuum container 2 from a periphery of the susceptor 5.

A circular-cylindrical discharging electrode 10 is provided as discharging means for exciting gas to be supplied. The discharging electrode 10 is disposed at a central portion of a cylindrical outer periphery of the vacuum container 2 and surrounds a central plasma producing region 9 of the reaction chamber 1. High frequency electric power applying means 14 is connected to the discharging electrode 10 through an impedance matching device 13.

Ring-like permanent magnets 11 are provided as magnetic lines of force-forming means. The permanent magnets 11 are disposed at upper and lower portions of an outer surface of the discharging electrode 10. The upper and lower permanent magnets 11 and 11 are provided at their opposite ends (inner peripheral end and outer peripheral end) along a radial direction of the vacuum container 2 with magnetic poles, and directions of the magnetic poles of the upper and lower permanent magnets 11 and 11 are set opposite. Therefore, poles of the magnetic poles of the inner peripheral portion are opposite from each other, and poles of the magnetic poles of the outer peripheral portion are opposite from each other. With this arrangement, magnetic lines of force are formed in an axial direction of the cylindrical discharging electrode 10 along an inner peripheral surface of the discharging electrode 10.

The susceptor 5 on which the substrate W is placed is disposed on a central portion of the bottom in the vacuum container 2. The susceptor 5 can heat the substrate W. The susceptor 5 is made of aluminum nitride for example, and a resistance heating heater as heating means is integrally embedded in the susceptor 5. The resistance heating heater can heat the substrate up to about 500° C.

The susceptor 5 further includes an electrode in the heater. The electrode is grounded through an impedance variable mechanism 15. The impedance variable mechanism 15 comprises a coil and a variable capacitor, as mentioned below, and by controlling the number of patterns of the coil or a capacity value of the capacitor, an electric potential of a substrate W can be controlled through the above-mentioned electrode and the susceptor 5.

If the number of patterns of the coil or the capacity of the capacitor is changed, and potential of the susceptor 5, the impedance of the susceptor 5 or a potential difference between the susceptor 5 and the plasma producing region is adjusted, there is a remarkable effect for increasing the thickness of the oxide film as thick as 30 to 60 Å by the MMT apparatus. Although it is possible to increase the film thickness by increasing electric power, increasing the processing time, adjusting the processing temperature or other method, it is not possible to increase the thickness of the oxide film as thick as 30 to 60 Å without providing a coil or a capacitor and changing the number of patterns of the coil or the capacity of the capacitor. The same can be said for a nitride film also. By changing the number of patterns of the coil or the capacity of the capacitor, and adjusting the potential of the susceptor 5, the impedance of the susceptor 5 or a potential difference between the susceptor 5 and the plasma producing region in this manner, it is possible to adjust a thickness of a film in a wide range, that is, from a thin film to a thick film.

The susceptor 5 is insulated from the vacuum container 2, and the vacuum container 2 is grounded. Gas supplying means (not shown) such as a cylinder is connected to the gas-introducing opening 6 to form a gas-introducing system (not shown). The gas-exhausting opening 12 is connected to a vacuum pump (not shown). A valve (not shown) for adjusting a pressure in the vacuum container 2 is disposed in the vicinity of the gas-exhausting opening 12, which constitutes a vacuum exhausting system.

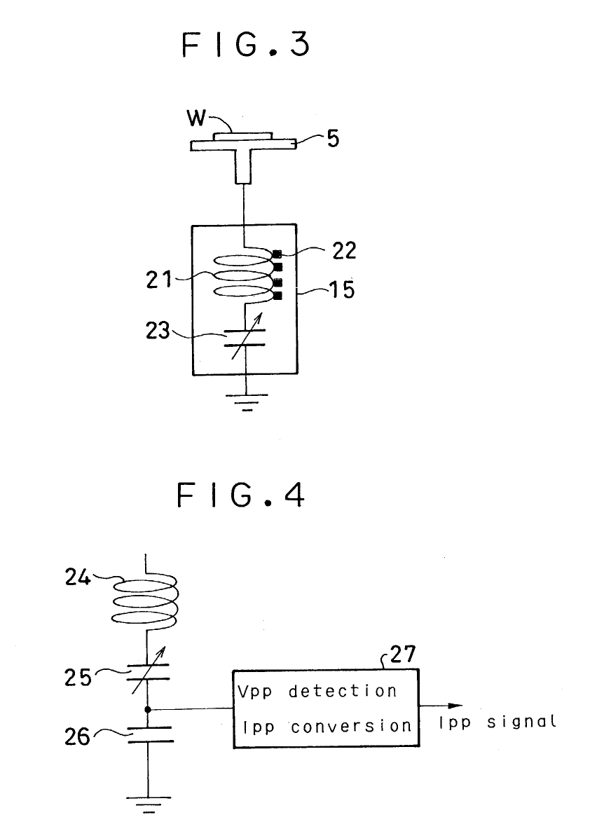

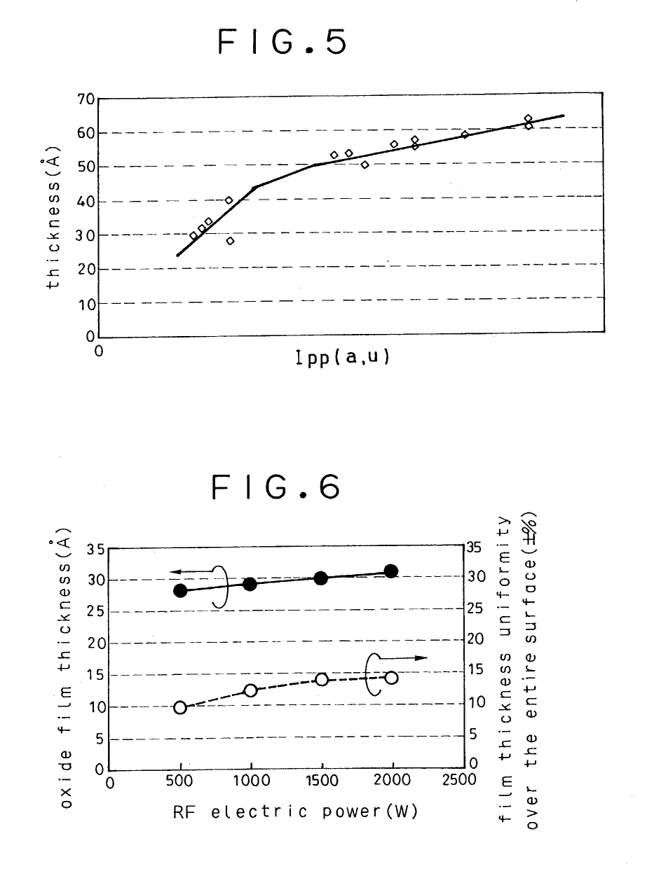

FIG. 3 shows an internal circuit of the impedance variable mechanism 15. The circuit includes no power supply, and comprises passive elements only. More specifically, the coil 21 and the capacitor 23 are connected to each other in series. The coil 21 and the capacitor 23 are connected between the susceptor 5 and the earth. The coil 21 is provided at its several locations with terminals 22. The terminals 22 are arbitrarily short-circuited to control the number of patterns of the coil so that a desired inductance value can be obtained. A variable capacitor capable of linearly varying the electrostatic capacity of its own is used as the capacitor 23. An electric potential of the substrate W can be controlled by adjusting at least one of the coil 21 and the capacitor 23 and by adjusting the impedance of the impedance variable mechanism 15 to a desired value.

In the above-described structure, a method for subjecting a surface of a substrate such as silicon or a surface of a lower film formed on a silicon substrate to oxidation processing or nitriding processing will be explained.

A substrate W is transferred into the vacuum container 2 from outside by substrate transfer means (not shown) such as a robot, and is moved onto the susceptor 5. The heater embedded in the susceptor 5 is previously heated, and the heater heats the substrate W to a predetermined temperature within a range from a room temperature to 700° C. which is most suitable for surface processing. A vacuum pressure in the vacuum container 2 is maintained using an exhausting pump (not shown), and the pressure is maintained within a range of 0.1 to 100 Pa. The gas pressure in the vacuum container 2 is determined by a flow rate of processing gas introduced from the gas-introducing opening 6, ability of a pump (not shown) connected to the gas-exhausting opening 12, exhausting conductance to the pump, and a valve (not shown) for adjusting a pressure.

After the substrate W is heated to the predetermined temperature, oxygen O₂ or nitrogen N₂ is supplied in a form of shower from the gas-introducing opening 6 through the gas-injecting holes 7 of the gas shower head 8 toward an upper surface (surface to be processed) of the substrate W in the vacuum container 2. The flow rate of gas at that time is in a range of 10 to 5,000 sccm. At the same time, high frequency electric power is applied to the discharging electrode 10 from the high frequency electric power applying means 14 through the impedance matching device 13. The electric power to be applied is in a range of 150 to 2,000W. At that time, the impedance variable mechanism 15 is previously controlled to a desired impedance value.

Magnetron discharge is generated due to an influence of magnetic fields of the permanent magnets 11 and 11, electric charge is trapped in a space above the substrate W and high concentration plasma 9 is produced. By the produced high concentration plasma 9, a surface of the substrate W on the susceptor 5 is subjected to plasma oxidation processing or plasma nitriding processing. The surface processing is started and finished by supplying high frequency electric power and stopping the supply. The substrate W whose surface was processed is transferred out from the vacuum container 2 using the transfer means, the vacuum container 2 receives a next substrate W, and the substrate W is subjected to the same processing.

Here, one example of substrate processing will be explained based on the nonvolatile memory using a semiconductor silicon substrate as the substrate W.

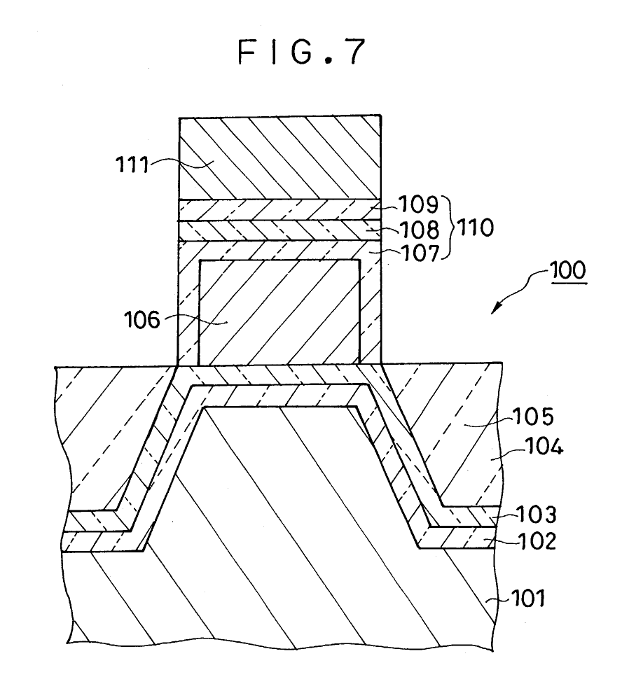

FIG. 7 is a schematic longitudinal sectional view showing one example of a nonvolatile memory. A Sio₂ film 102 is formed on a surface of a silicon substrate 101 formed with a trench 104, and a SiN film 103 is formed on the Sio₂ film 102. A SiO₂ film 105 is embedded in the trench 104. A floating gate polycrystalline silicon 106 is formed on the SiN film 103. The floating gate polycrystalline silicon 106 is formed at its upper and side surfaces with a SiO₂ film 107. A SiO₂ film 108 is formed on the SiO₂ film 107, and a SiO₂ film 109 is formed on the SiO₂ film 108. The SiO₂ film 107, the SiO₂ film 108 and the SiO₂ film 109 constitute a so-called ONO structure 110. A control gate polycrystalline silicon 111 is formed on the SiO₂ film 109.

The MMT apparatus of the present invention is preferably used when a surface of the silicon substrate 101 is oxidized and the SiO₂ film 102 is formed, when the Sio₂ film 102 is nitrided and SiN film 103 is formed, when the upper and side surfaces of the floating gate polycrystalline silicon 106 are oxidized and the SiO₂ film 107 is formed, and when the SiO₂ film 107 is nitrided and the SiO₂ film 108 is formed. If the SiO₂ film 108 is formed using the CVD method, the MMT apparatus of the embodiment can preferably be used for oxidizing the SiO₂ film 108 and forming the SiO₂ film 109.

When the SiO₂ film 102 is nitrided to form the SiN film 103, the interface between the SiO₂ film 102 and the SiN film 103 becomes an oxynitride film in which oxygen and nitrogen are mixed. A film at a distance from the interface is called a SiO₂ film from a point where a nitrogen concentration becomes, for example, 5% or lower, and a film at a distance from the interface is called a SiN film from a point where an oxygen concentration becomes, for example, 5% or lower. At the interface between the SiO₂ film 107 and SiN film 108 and the interface between the SiN film 108 and the SiO₂ film 109 are formed oxynitride films in the same manner as the the interface between the SiO₂ film 102 and the SiN film 103.

When a surface or a lower film surface of the substrate W is subjected to the oxidation processing or the nitriding processing, an impedance of the impedance variable mechanism 15 interposed between the susceptor 5 and the earth is previously controlled to a desired value. If the impedance of the impedance variable mechanism 15 is adjusted to the desired value, the electric potential of the substrate W is controlled accordingly, and it is possible to form an oxide film or a nitride film having a desired film thickness and uniformity of film thickness over the entire surface of the film.

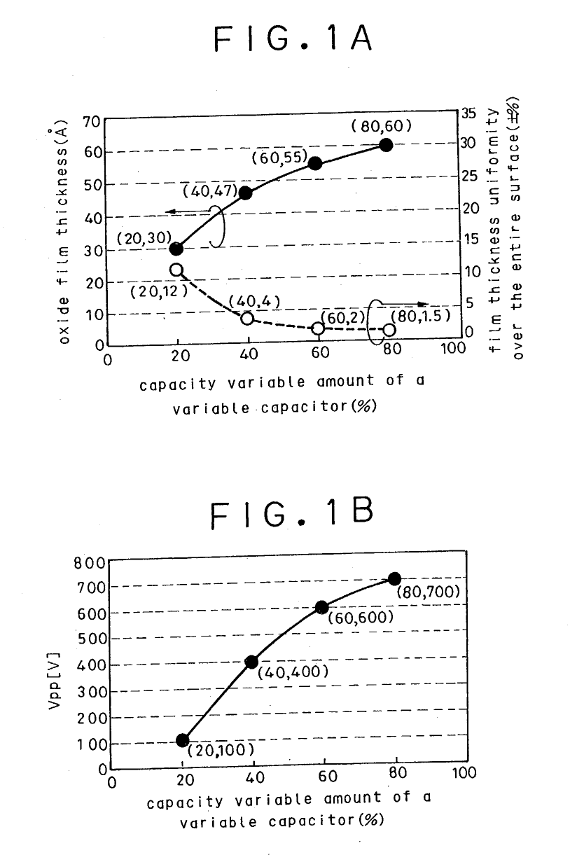

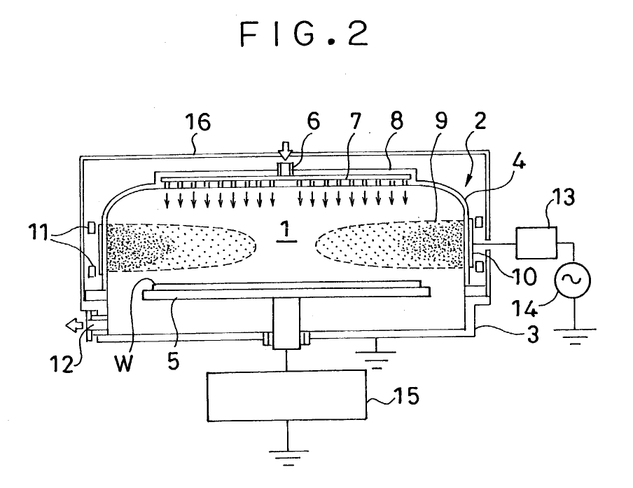

FIGS. 1A and 1B show variation of characteristics of an oxide film while taking the case of oxidation processing as substrate surface processing. The oxidation processing conditions are as follows: a temperature is 400° C., a pressure is 20 Pa, high frequency electric power is 500W, oxygen O₂ of 500 sccm, and time is one minute. FIG. 1A shows a thickness of the oxide film and characteristics of film thickness uniformity over the entire surface wherein a lateral axis shows a capacity variable amount (%) (variable capacitor position) of a variable capacitor which constitutes the impedance variable mechanism 15, a left vertical axis shows a thickness (Å) of the oxide film, and a right axis shows film thickness uniformity over the entire surface (±%). FIG. 1B shows voltage characteristics wherein a lateral axis shows a capacity variable amount (%) (variable capacitor position) of a variable capacitor and a vertical axis shows peak-to-peak voltage Vₚₚ in the impedance variable mechanism which corresponds to potential of a substrate. This voltage Vₚₚ is high frequency voltage of connection point between later-described variable capacitor 25 and fixed capacitor 26 shown in FIG. 4.

It is found from FIG. 1A that if the impedance of the impedance variable mechanism 15 inserted between the susceptor 5 and the ground is changed, film characteristics are changed. Since the film characteristics are changed relatively linearly, it is easy to control the film thickness and the uniformity of the thickness. Further, if the capacity of the variable capacitor is changed in a range of 20 to 80%, it is possible to widely control the film thickness from about 30 Å to about 60 Å. If the capacity of the variable capacitor is changed in a range of 20 to 80%, it is possible to widely control the film thickness uniformity over its entire surface in a range of ±12 to ±1.5%. Further, if the impedance is increased, it is possible to increase the thickness of the oxide film and to improve the film thickness uniformity over its entire surface.

It is found from FIG. 1B that if the capacity of the variable capacitor is changed in a range of 20 to 80%, the peak-to-peak voltage Vₚₚ is changed in a range of 100 to 700V. Therefore, if the potential of the susceptor is controlled, it is possible to control the thickness of the oxide film in a range of 30 to 60 Å, and, as explained in the above referring to FIG. 1A, to control the uniformity of the film thickness over its entire surface in a range of ±12 to ±1.5%. If the peak-to-peak voltage Vₚₚ is set to 100V or lower, or to 700V or higher, it is possible to widen the control range of the potential of the susceptor, and to further widen the controllable ranges of the thickness of the oxide film and the uniformity of the film thickness over its entire surface. The potential of the susceptor can be controlled by the variable impedance mechanism 15 constituted by a passive device, but since the potential is under the domination of voltage applied to the discharging electrode 10, the potential can not be controlled without limitation. The reason is as follows. That is, if an output value of the high frequency electric power is about 500W for example, the peak-to-peak voltage Vₚₚ applied to the discharging electrode 10 becomes about 700V. The susceptor 5 becomes an antenna inserted into an electric field space generated by the applied electric power of the discharging electrode 10. The strength of electromagnetic wave which can be received by the antenna does not become greater than voltage of the discharging electrode 10 which is a sender and thus, the upper limit of the susceptor potential Vₚₚ becomes about 700V under the above-described process condition.

According to the present embodiment as described above, when a surface of a substrate W or a surface of a lower film is subjected to the oxidation processing, if the capacity of the variable capacitor of the impedance variable mechanism 15 is controlled to adjust the substrate potential, it is possible to form a thin film having desired thickness and uniformity of the film thickness over its entire surface.

In the embodiment, since the impedance variable mechanism constituted by a passive device circuit having no power source is used to control the substrate potential, the control is easy and the structure is simple as compared with a mechanism using a high frequency power source or a low frequency power source.

The embodiment uses the MMT apparatus capable of controlling energy of ion which is emitted to a substrate independently from plasma production, and the energy of the ions emitted to the substrate is independently controlled by the impedance variable mechanism. Therefore, a film thickness is almost determined by the capacity set value of the impedance variable mechanism, and the film thickness does not depend on other process conditions. Therefore, the process conditions of the present invention can be applied in all controllable range. The process conditions have already been described, and the conditions are listed below.

Temperature range room temperature to 700° C.

Pressure range 0.1 Pa to 100 Pa

Gas flow rate 10 sccm to 5,000 sccm

High frequency electric power 150W to 2,000W

The parallel flat plate type plasma processing apparatus which controls an output value of the high frequency electric power or controls the supply of bias electric power can not control the film thickness by controlling the impedance using the above-described MMT apparatus. In principle, it is possible for the parallel flat plate type plasma processing apparatus to form an oxide film or a nitride film of 3 nm or more if the susceptor voltage is increased. However, the parallel flat plate type plasma processing apparatus can not independently control the discharging voltage and the susceptor voltage. Therefore, if the susceptor voltage is increased, strong electric field is applied to the substrate and thus, a film quality is deteriorated by plasma damage, and the uniformity of film thickness is also deteriorated. In the MMT apparatus of the embodiment, electric field is applied to the discharging electrode, electric charge is trapped by the magnetic lines of force, thereby increasing the plasma density as compared with the parallel flat plate type plasma processing apparatus. Further, in order to enhance the plasma processing efficiency, susceptor potential which can be controlled independently from plasma production is controlled instead of the voltage of the discharging electrode which produces plasma. Therefore, the substrate is not damaged by plasma, and a quality of a formed film can excellently be maintained. The MMT apparatus can increase the film thickness of 6 nm or more if the susceptor potential is controlled to several hundreds V, but if the susceptor potential is not controlled, since the susceptor potential is only about 10 to 20V, even the MMT apparatus can not realize a thick film of 3 nm or more.

In the above embodiment, it is necessary to control the impedance of the impedance variable mechanism while monitoring an electric state of a surface of a substrate. As a factor which reflects the electric state of the substrate surface, it is preferable to use a factor which is strong with respect to film thickness characteristics in view of a result of the substrate processing. Here, the most simple and easiest factor is a method for monitoring the high frequency voltage Vₚₚ in the impedance variable mechanism 15. However, the method for monitoring Vₚₚ has unclear portion in causality with respect to the film thickness and the like. This is because that the susceptor itself has floating impedance, electric characteristics of plasma are also changed by impedance control and thus, physical meaning of the high frequency voltage Vₚₚ at the monitored point becomes unclear.

In this point, the method for monitoring the high frequency current Ipp flowing into the susceptor (substrate) has no equivocality in the above-described physical meaning. Further, it is found by recent experiment that a strong factor which affects the film thickness characteristics in the nitriding processing is the high frequency current Ipp flowing into a susceptor (substrate). Therefore, it is preferable to monitor the electric state of the substrate surface using current, not voltage.

FIG. 4 is an explanatory view of impedance control using a current monitor. Current in the impedance variable mechanism 15 inserted between the susceptor and the ground is monitored, and the variable capacitor is feedback controlled such that the current becomes the optimal value. As shown in FIG. 4., a series circuit comprising a coil 24 and the variable capacitor 25 is formed on the susceptor, and the fixed reactance (capacitor or coil) 26 is connected between the variable capacitor 25 and the ground. High frequency voltage Vₚₚ applied to the fixed reactance 26 is detected, the detected voltage is converted into current, thereby monitoring high frequency current Iₚₚ flowing into the susceptor. A circuit which operates a variable capacitor position of the variable capacitor 25 of the impedance variable mechanism 15 is feedback controlled by a signal of the monitored high frequency current, thereby controlling the high frequency current flowing into the substrate (susceptor).

FIG. 5 shows film thickness characteristics with respect to the high frequency current which is controlled in this manner. A lateral axis shows high frequency current Iₚₚ (a.u. (arbitrary unit)), and a vertical axis shows film thickness (Å). It is found that if the high frequency current is increased from this state, it is possible to change the film thickness linearly from 3 nm to 6 nm.

Therefore, according to the above-described method for controlling the high frequency current, high frequency voltage applied to the reactance having the fixed impedance is monitored, the monitored voltage is converted into high frequency current and then, the high frequency current is feedback to the variable capacitor. Thus, stable high frequency current Iₚₚ can be obtained and as a result, stable substrate processing can be realized. Further, since the substrate surface state is controlled by the strong high frequency current Iₚₚ which affects the substrate processing characteristics, it is possible to change the film thickness over the wide range. Furthermore, since it is only necessary to convert the high frequency voltage into current, the apparatus can utilize the impedance variable mechanism as it is, and the controlling method is simple and inexpensive.

If the nitriding processing or oxidation processing step which is carried out in the above-described embodiment, its antecedent step and subsequent step are continuously carried out in the same vacuum chamber, it is possible to stably carry out the nitriding processing or oxidation processing, and to enhance the characteristics of the semiconductor device.

The entire disclosure of Japanese Patent Application No. 2002-101103 filed on Apr. 3, 2002 and Japanese Patent Application No. 2002-145759 filed on May 21, 2002 including specifications, claims, drawings and abstracts are incorporated herein by reference in its entirety.

Although various exemplary embodiments have been shown and described, the invention is not limited to the embodiments shown. Therefore, the scope of the invention is intended to be limited solely by the scope of the claims that follow.

What is claimed is:

1. A producing method of a semiconductor device using a plasma processing apparatus including a processing chamber, a substrate supporting body which is to support a substrate in the processing chamber, and a cylindrical electrode and a magnetic lines of force-forming device which are disposed around the processing chamber, comprising:
supplying gas including oxygen element into the processing chamber, and
plasma-discharging said gas including oxygen element by a high frequency electric field obtained by supplying a high frequency electric power to the cylindrical electrode and a magnetic field obtained by the magnetic lines of force-forming device to oxidize an object to form an oxide film having a thickness of 30 to 60 Å.

2. A producing method of a semiconductor device using a plasma processing apparatus including a processing chamber, a substrate supporting body which is to support a substrate in the processing chamber, a coil and a capacitor which are connected between the substrate supporting body and a reference potential, and a cylindrical electrode and a magnetic lines of force-forming device which are disposed around the processing chamber, comprising:
supplying substrate processing gas into the processing chamber, and
plasma-discharging said substrate processing gas by a high frequency electric field obtained by supplying a high frequency electric power to the cylindrical electrode and a magnetic field obtained by the magnetic lines of force-forming device to form an oxide film, a nitride film or an oxynitride film, wherein
a thickness of the oxide film, a thickness of the nitride film or a thickness of the oxynitride film is changed by changing at least a number of windings of the coil or changing a capacity of the capacitor.

3. A semiconductor device producing apparatus, comprising:
a processing chamber;
a substrate supporting body which is to support a substrate in said processing chamber;
a coil and a capacitor which are connected between said substrate supporting body and a reference potential, at least one of a number of windings of said coil and a capacity of said capacitor being variable; and
a cylindrical electrode and a magnetic lines of force-forming device which are disposed around said processing chamber, wherein
substrate processing gas is supplied into said processing chamber, and
said substrate processing gas is plasma-discharged by a high frequency electric field obtained by supplying a high frequency electric power to said cylindrical electrode and a magnetic field obtained by said magnetic lines of force-forming device.

4. A semiconductor device producing apparatus as recited in claim 3, wherein
plasma oxidizing and plasma nitriding can be effected in said semiconductor device producing apparatus, and
when said plasma oxidizing and said plasma nitriding are switched, the number of windings of said coil is adjusted or the capacity of said capacitor is changed.

5. A semiconductor device producing apparatus, comprising:
a processing chamber;
a substrate supporting body which is to support a substrate in said processing chamber; and
a cylindrical electrode and a magnetic lines of force-forming device which are disposed around said processing chamber, wherein
substrate processing gas is supplied into said processing chamber,
said substrate processing gas is plasma-discharged by a high frequency electric field obtained by supplying a high frequency electric power to said cylindrical electrode and a magnetic field obtained by said magnetic lines of force-forming device to form an oxide film, a nitride film or an oxynitride film, and
a thickness of said oxide film, a thickness of said nitride film or a thickness of said oxynitride film is changed by changing one of an electric potential of said substrate supporting body, an impedance of said substrate supporting body, and an electric potential difference between said substrate supporting body and a plasma producing region.

6. A producing method of a semiconductor device using a plasma processing apparatus including a processing chamber, a substrate supporting body which is to support a substrate in the processing chamber, and a cylindrical electrode and a magnetic lines of force-forming device which are disposed around the processing chamber, comprising:
supplying substrate processing gas into the processing chamber, and
plasma-discharging said substrate processing gas by a high frequency electric field obtained by supplying a high frequency electric power to the cylindrical electrode and a magnetic field obtained by the magnetic lines of force-forming device to form an oxide film, a nitride film or an oxynitride film, wherein
a thickness of said oxide film, a thickness of said nitride film or a thickness of said oxynitride film is changed by changing one of an electric potential of said substrate supporting body, an impedance of said substrate supporting body, and an electric potential difference between said substrate supporting body and a plasma producing region.

7. A producing method of a semiconductor device as recited in claim 1, wherein
said object is one of a silicon substrate, a polycrystalline silicon film and a nitride film.
